(19) United States
(12) Patent Application Publication
(10) Pub. No.: US 2025/0369150 A1
(43) Pub. Date: Dec. 4, 2025

(54) INJECTION SYNTHESIS METHOD FOR SEMICONDUCTOR COMPOUND

(71) Applicant: THE 13TH RESEARCH INSTITUTE OF CHINA ELECTRONICS TECHNOLOGY GROUP CORPORATION, Shijiazhuang, Hebei (CN)

(72) Inventors: Yanlei Shi, Shijiazhuang, Hebei (CN); Niefeng Sun, Shijiazhuang, Hebei (CN); Shujie Wang, Shijiazhuang, Hebei (CN); Zheng Liu, Shijiazhuang, Hebei (CN); Lijie Fu, Shijiazhuang, Hebei (CN); Chengyan Xu, Shijiazhuang, Hebei (CN); Jingkai Qin, Shijiazhuang, Hebei (CN); Huimin Shao, Shijiazhuang, Hebei (CN); Yang Wang, Shijiazhuang, Hebei (CN); Xiaolan Li, Shijiazhuang, Hebei (CN); Huisheng Liu, Shijiazhuang, Hebei (CN); Xiaodan Zhang, Shijiazhuang, Hebei (CN); Xuefeng Zou, Shijiazhuang, Hebei (CN); Wei Wang, Shijiazhuang, Hebei (CN); Xin Zhang, Shijiazhuang, Hebei (CN); Yaqi Li, Shijiazhuang, Hebei (CN); Hongfei Zhao, Shijiazhuang, Hebei (CN); Yong Kang, Shijiazhuang, Hebei (CN)

(21) Appl. No.: 18/995,072

(22) PCT Filed: Dec. 14, 2022
(86) PCT No.: PCT/CN2022/138856

§ 371 Date: Jan. 15, 2025

(30) Foreign Application Priority Data
Jul. 15, 2022 (CN) 202210829110.3

(51) Int. Cl. C30B 11/06; C30B 11/00; C30B 29/52

(52) U.S. Cl. CPC C30B 11/065; C30B 11/006; C30B 29/52

(57) ABSTRACT

A semiconductor compound injection synthesis method relating to the synthesis of semiconductor materials, being implemented on the basis of a synthesis system. The synthesis system adopts an open gas source device. The method includes: placing materials, probing the open gas source device, melting metal materials, and gasifying the gas source material to complete the synthesis. Beneficial effects: in the synthesis method of the present invention, the lower part of the baffle of the open gas source device is a reaction chamber. During the synthesis, the contact area between the gas source material and the melt is at least 22 times the contact area of the traditional double-tube method. In the present invention, there is no isolation of the covering agent in the reaction chamber, and the two reaction elements are always in contact at the liquid surface. In a specific implementation case, when the method of the present invention is used to synthesize phosphating steel materials, compared with the traditional double-tube injection method, the efficiency of the method is improved by 12 times.

### FIELD

The present invention relates to the synthesis of semiconductor materials, and in particular to a method for synthesizing compound semiconductor materials by adopting an improved injection method.

### BACKGROUND

Compound semiconductor materials are one of the important basic supporting technologies for the development of the electronic information industry technology system. They are widely used in optical fiber communications, mobile communications, navigation, detection and other fields, and have become a hot spot for countries to compete for development.

Compound semiconductor materials mainly involve material synthesis and single crystal growth, and the methods of material synthesis mainly include diffusion method and injection method.

In the preparation processes of phosphated steel, gallium phosphate, gallium phosphide, gallium phosphate, zinc phosphate and other materials, the injection method is generally used for synthesis due to the characteristics of the materials. For example, issued Chinese patents including application Ser. Nos. 20/201,0487276.2, 202110618242.7, 201911155615.0, and 202110145424.7 all disclose technical solutions for synthesizing compound semiconductor materials using a gas injection device: after the volatile gas source material is heated and vaporized, the vaporized elements are injected into the melt through an injection tube to complete the synthesis.

The current technology has the following problems:

1. Slow reaction speed. In practice, we found that the synthesis speed of the compound depends on the contact area between the gas of the volatile element and the melt. Calculations show that the main reaction opportunities of the injection method are mainly at the opening of the tube and inside the tube. The diameter of the injection method tube pin is often between 8-20 mm. Even in the double-tube synthesis method, the contact area between the volatile element and the melt is limited. There will be absorption during the process of the bubble rising, but the rising time is short and the amount of absorption is very limited.

2. Waste of gas source material loss. Theoretically, if the vaporization rate of the volatile element is equal to its reaction rate with the melt, no bubbles will emerge. However, it is difficult to match the vaporization rate and the reaction rate in actual process operation. When the vaporization rate of the volatile element is lower than the reaction rate, the melt will be sucked into the pin, causing the pin to be blocked, resulting in failure of the synthesis process. When the vaporization rate of the volatile element is greater than the chemical reaction rate, the excess volatile elements emerge in the form of bubbles. The time from the emergence of bubbles in the melt to the overflow of the melt surface is very short, and they are almost not absorbed by the melt. In addition, in the actual process, to ensure that back suction does not occur in the pin, the method of increasing the vaporization rate of the volatile element (increasing the power of the volatile element heater) is often used, thereby exacerbating the overflow of the volatile element. During the rising process, the bubbles will react with the melt, but because the bubbles rise very quickly, only a very small part is absorbed by the melt. There are also covering agents such as oxide on the surface of the melt, which isolates the substances involved in the synthesis. The escaped bubbles will not participate in the synthesis process, resulting in waste.

In the prior art, there is also a technical solution of increasing the number of injection pipes, thereby increasing the injection amount of gas source material per unit time, but the contact time is not improved and the problem of gas source material waste is not solved.

### SUMMARY

The purpose of the present invention is to provide a synthesis method to increase the contact area and contact time between reaction elements, thereby improving the synthesis efficiency.

To achieve the purpose of the invention, the technical solution adopted by the present invention is: a semiconductor compound injection synthesis method, completed by a semiconductor synthesis system, and the key is: the open gas source device is sealed at the top and open at the bottom, the diameter of the opening is smaller than the inner diameter of the crucible, a baffle with breathing holes is arranged in the middle of the open gas source device, and a gas source heater is arranged on the periphery of the open gas source device.

The method comprising:
1-1. Place the gas source material required for synthesis on the baffle of the open gas source device, and insert the open gas source device into the crucibles.
1-2. Treat the metal material required for synthesis, and place the treated metal material into the crucibles.
1-3. Place a covering agent on the metal material.
1-4. Turn on the crucible heater.
1-5. After the metal material melts, the open gas source device moves downward, and its lower edge approaches the bottom of the crucibles.
1-6. Raise the temperature of the crucibles to the synthesis temperature.
1-7. Turn on the gas source heater, and the gas source material is heated to the gasification temperature.
1-8. Control the power of the gas source heater and adjust the gasification rate of the gas source material.
1-9. The gas source material is completely gasified, and the reaction ends.

In addition to process conditions such as temperature and pressure, the main factors affecting the rate of chemical reaction are the contact area and contact time of the two elements. The reaction rate is proportional to the size of the contact area.

Beneficial effects: In the traditional injection method, the inner diameter of the gas source material gasification injection tube is 8-15 mm. Based on the inner diameter being 15 mm, the contact area of the single tube is 177 mm², and the contact area of the double tube is 354 mm²; while in the synthesis methods of the present invention, the lower part of the baffle of the open gas source device is the reaction chamber, and the diameter of the reaction chamber can be smaller than the inner diameter of the crucibles, usually 100-200 mm. Based on the diameter being 100 mm, during synthesis, the contact area between the gas source material and the melt is 7850 mm², which is at least 22 times the contact area of the traditional double tube.

In the present invention, there is no covering agent for isolation in the reaction chamber, and the two reaction elements are always in contact at the liquid surface.

In a specific implementation case, the method of the present invention is used to synthesize phosphating steel materials. Compared with the traditional double-tube injection method, the efficiency of this method is improved by 12 times. The reaction time is short, and the high-temperature phosphating steel melt is in contact with the crucibles for a short time, so the contamination is also reduced accordingly, and the purity of the material is significantly improved.

### BRIEF DESCRIPTION OF THE DRAWINGS

FIG. 1 is a schematic diagram of the structure of the synthesis system of the present invention;

FIGS. 2-4 are partial schematic diagrams of the synthesis system of the present invention under different working conditions;

FIG. 5 is a schematic diagram of the exhaust pipe of the system;

FIG. 6 is a schematic diagram of an embodiment of an open air source device,

FIG. 7 is a schematic diagram of another embodiment of an open air source device.

As shown in the figures: 1 is the furnace, 2 is the furnace heater, 3 is the open air source device, 4 is the baffle, 5 is the air vent, 6 is the air source heater, 7 is the connecting rod, 8 is the driving device, 9 is the observation hole, 10 is the furnace frame, 10-1 is the vacuum hole, 10-2 is the valve, 11 is the metal material, 12 is the covering agent, 13 is the air source material, 14 is the exhaust hole, 15 is the exhaust hole mounting seat, 16-1 is the exhaust hole plugging, 16-2 is the exhaust connector, 16-3 is the exhaust hole control float, 17 is the air inlet, 18 is the air inlet mounting seat, 19-1 is the air inlet plugging, 19-2 is the air inlet connector, 19-3 is the air inlet control float ball, 20 is the melt, 21 is the liquid covering agent, 22 is the exhaust pipe, and 23 is the exhausted air bubble.

### DETAILED DESCRIPTION

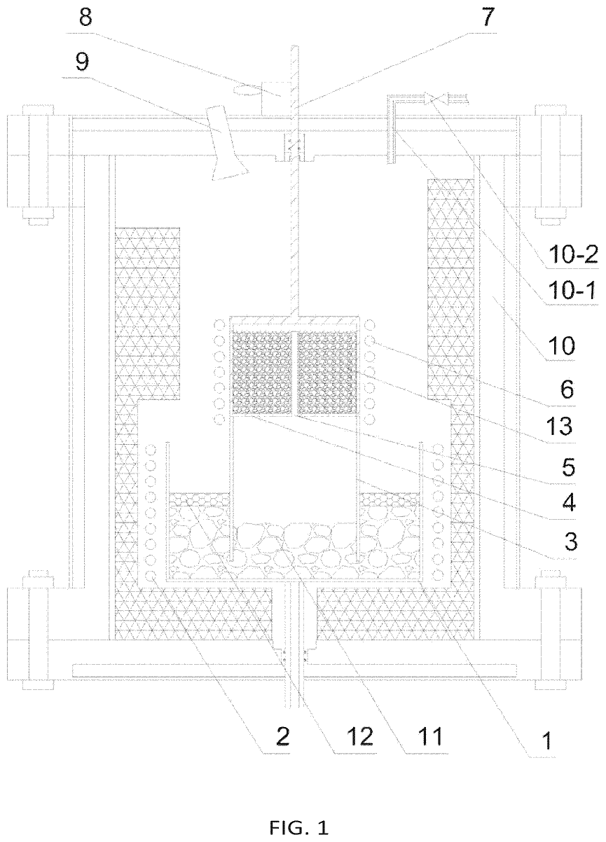

Referring to FIG. 1, the present invention is a completed based on a synthesis system, which includes a furnace frame 10, crucibles 1 in the furnace, a crucible heater 2, an open air source device 3, a baffle 4 with air holes 5 arranged in the middle of the open air source device 3, and a driving device 8 driving the open air source device 3 to move up and down through a connecting rod 7.

### Synthesis Process

Assemble the synthesis system. During the assembly process:

1-1. Place the gas source material 13 required for synthesis on the baffle 4 of the open gas source device 3, and insert the open gas source device 3 into the crucibles 1.

1-2. Process the metal material 11 required for synthesis, and put the processed metal material 11 into the crucibles 1.

1-3. Place a covering agent 12 on the metal material 11.

After the assembly is completed, the furnace body is evacuated through the vacuum hole 10-1, and then an inert gas is injected. The assembly process is a conventional technology in the art, which is not the focus of the present invention, and the drawings and text will not described it further.

First, the open air source device 3 is inserted into the crucibles 1, and then the processed metal material 11 is placed into the crucibles 1, and then the covering agent 12 is placed on the metal material 11, which can ensure that the covering agent is only arranged outside the open air source device 3, and after the covering agent 12 melts, it will not enter the coverage of the open air source device 3. The state of the synthesis system at this time is shown in FIG. 1.

1-4. Turn on the furnace heater 2 to heat the metal material 11 and the covering agent 12 inside the crucibles.

1-5. After the metal material 11 is melted, the open air source device 3 is moved downward, and its lower edge is close to the bottom of the crucibles, at a distance of 5-30 mm from the bottom of the crucibles.

1-6. Raise the temperature of the crucibles to the synthesis temperature, at which point the conditions for compound synthesis have been met.

1-7. Turn on the gas source heater 6, and heat the gas source material 13 to the gasification temperature. After gasification, the gas source material 13 enters the cavity below the partition 4 of the open gas source device 3 through the air vent 5, and the cavity is the reaction chamber for compound synthesis.

In the traditional injection method, the contact position of the two reaction elements is the injection nozzle; the bubbles will rise after injection and escape to the cover agent, and no longer participate in the reaction, resulting in waste.

In the present invention, in the reaction chamber, there is no isolation of the covering agent, the two reaction elements are always in contact at the liquid surface, and the contact area is the area of the opening below the open gas source device 3, the contact time and contact area of the two reaction materials are greatly improved, and the synthesis efficiency is improved.

At the periphery of the reaction chamber, the covering agent is used to prevent the material from dissociating, that is, to prevent the volatile elements from escaping from the melt.

Inside the sealed reaction chamber, the phosphorus elements inside and outside the melt are balanced, and phosphorus volatilization will not occur, and no oxidation covering is required.

1-8. Control the power of the gas source heater 6 and adjust the gasification rate of the gas source material 13.

The gas source material 13 is always being gasified and supplied, and the synthesis of the two substances in the reaction chamber is always in progress. The speeds of the two substances are not matched, and the gas pressure inside and outside the reaction chamber is unbalanced, resulting in changes in the melt level inside and outside the reaction chamber. Severe cases may lead to: 1. The gas pressure outside the reaction chamber is high, and the melt level inside the reaction chamber rises above the partition 4, which may block the air hole 5, causing process to fail; 2. The gas pressure in the reaction chamber is too high, and the liquid metal is pressed out of the reaction chamber as a whole, causing the synthesis system to vibrate violently.

To avoid the above-mentioned accident, one method is to monitor the liquid level in the reactor and the reaction chamber in real time through the observation hole 9, control the power of the gas source heater 6, and adjust the gasification rate of the gas source material 13, so that the melt liquid level in the open gas source device 3 is basically consistent with the melt liquid level in the reactor 1.

1-9. The gas source material 13 is completely gasified and the reaction ends.

After the reaction is completed, the open air source device 3 is raised to separate the covering agent liquid level from the bottom edge of the reaction chamber; a cooling program is set and the furnace is dismantled.

There are some problems in controlling the power of the gas source heater 6 and adjusting the gasification rate of the gas source material 13 by observing the liquid level: 1. It is too dependent on the manual method; 2. The adjustment is delayed and will not be timely.

To solve the above problems, the present invention proposes the following solution: In the open air source device, a vent hole is provided at the lower part adjacent to the baffle, and the vent hole is opened and closed by a float ball.

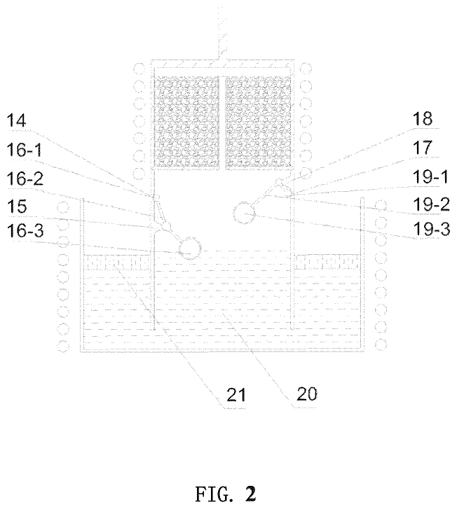

Referring to FIG. 2, two vent holes are provided, which are divided into an exhaust hole 14 and an intake hole 17 according to their functions.

The exhaust connector 16-2 is connected to the exhaust hole mounting seat 15, and the connecting arms at both ends of the exhaust connector 16-2 are respectively connected to the exhaust hole plug 16-1 and the exhaust hole control float ball 16-3. The melt 20 liquid level controls the exhaust hole control float ball 16-3 to float up and down, driving the exhaust hole plug 16-1 to plug and leave the exhaust hole 14.

Similarly, the air inlet connector 19-2 is connected to the air inlet mounting seat 18, and the connecting arms at both ends of the air inlet connector 19-2 are respectively connected to the air inlet plug 19-1 and the air inlet control float 19-3, and the melt 20 liquid level controls the air inlet control float ball 19-3 to float up and down, driving the air inlet plug 19-1 to leave and plug the air inlet 17.

FIG. 2 shows a situation where the pressure inside and outside the reaction chamber is relatively balanced, and both the exhaust hole 14 and the air inlet hole 17 are blocked.

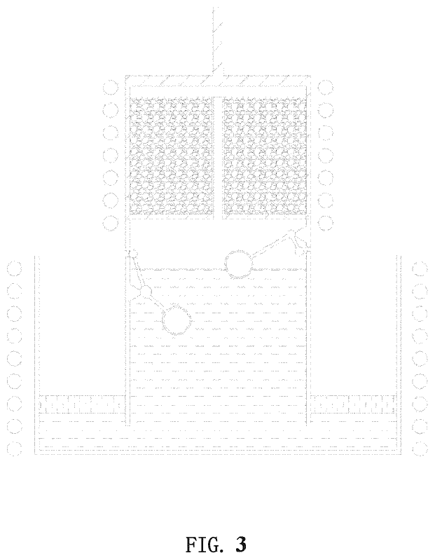

When the pressure inside the reaction chamber is lower than the external pressure, the liquid level of the melt 20 will rise, as shown in FIG. 3. At this time, the liquid level of the melt 20 drives the air inlet control float ball 19-3 to rise, and the air inlet plug 19-1 leaves the air inlet 17. The inert gas outside the reaction chamber enters the reaction chamber, and the liquid level of the melt 20 drops, driving the air inlet control float ball 19-3 to rise, and the air inlet plug 19-1 re-seals the air inlet 17, thereby sealing the reaction chamber.

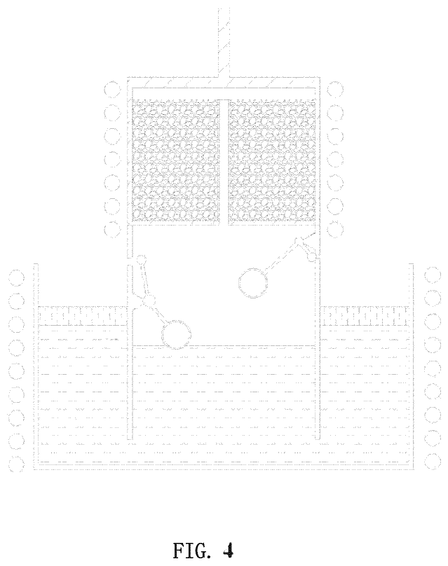

When the pressure inside the reaction chamber is greater than the external pressure, the liquid level of the melt 20 will drop, as shown in FIG. 4. At this time, the liquid level of the melt 20 drives the exhaust hole control float 16-3 to drop, and the exhaust hole plug 16-1 leaves the exhaust hole 14. The gas source material 13 in the reaction chamber is discharged from the reaction chamber. The liquid level of the melt 20 rises, driving the exhaust hole control float 16-3 to rise, and the exhaust hole plug 16-1 re-blocks the exhaust hole 14, sealing the reaction chamber.

The following points should be noted in the above settings:

1. The positions of the exhaust hole 14 and the air inlet 17 in the reaction chamber should be high enough to prevent the melt level in the reaction chamber from exceeding the exhaust hole 14 and the air inlet 17;

2. When the exhaust hole 17 is blocked, the position of the exhaust hole control float ball 19-3 is lower than the position of the exhaust hole 17. The specific restriction is: the horizontal position of the center of the exhaust hole 17 should be higher than the horizontal position of the center of the exhaust hole control float ball 19-3 when there is no melt 20, to prevent the liquid level of the melt 20 in the reaction chamber from exceeding the exhaust hole 17;

3. The weight of the air inlet control float 19-3 should meet the following requirements: under the lever principle of the air inlet connector 19-2, the air inlet block 19-1 can resist the pressure of the furnace body, and will not leave the air inlet 17 unless the melt 20 liquid level drives the air inlet control float ball 19-3 to rise.

4. The buoyancy of the float ball when it is completely immersed in the melt is more than 5 times the weight of the float itself.

The exhaust hole 14 and the air inlet 17 can be provided so that the synthesis device can be operated automatically without much human intervention. At the same time, the liquid level of the melt 20 rises and falls repeatedly, which can disturb the melt 20 and speed up the synthesis speed.

However, when the pressure inside the reaction chamber is greater than the external pressure, the gas source material 13 in the reaction chamber will be discharged from the reaction chamber to the furnace body, resulting in a waste of the gas source material 13.

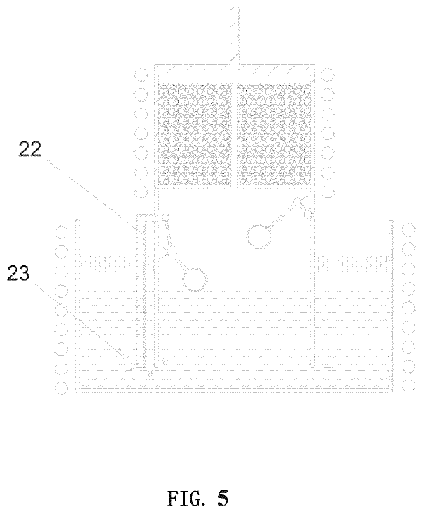

In this regard, the present invention has made further improvements: the exhaust hole 14 is externally connected to the exhaust pipe 22, and the exhaust pipe extends to the lower edge of the open air source device 3, as shown in FIG. 5.

When the pressure inside the reaction chamber is greater than the external pressure, the gas source material 13 inside the reaction chamber enters the bottom of the melt 20 through the exhaust hole 14 and the exhaust pipe 22. During the rising process, most of the discharged bubbles 23 will be absorbed by the melt 20, a small part will enter the reaction chamber, and some will escape and pass through the covering agent 11 into the furnace body. Compared with the traditional injection method, the loss of the gas source material 13 caused by the escape is very small.

There can be 1 to 6 exhaust pipes 22 connected to the exhaust hole 14, that is, one exhaust hole and multiple outlets. If multiple exhaust pipes 22 are provided, the exhaust pipes 22 are evenly arranged along the periphery of the open air source device 3, and the exhausted bubbles 23 are distributed in a wider range in the melt 20, thereby improving the absorption efficiency.

In the above embodiments, the open air source device 3 is a cylindrical structure.

The purpose of the present invention is to provide a reaction chamber that allows two reaction substances to contact for a long time and over a large area. If a cylindrical structure with uniform top and bottom is adopted, the diameter of the container carrying the gas source material 13 will inevitably increase, which may cause the diameter to be too large and the inside and outside to be uneven during heating.

In this regard, the present invention proposes other open air source device 3 structures.

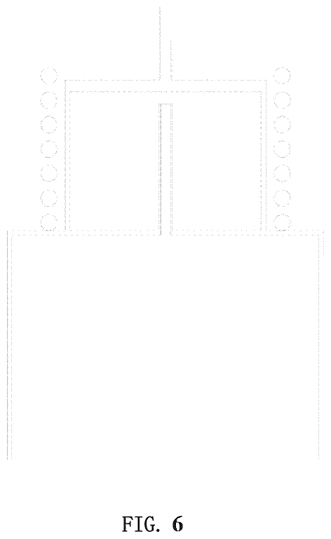

1. The open gas source device 3 is composed of two cylinder structures, which are separated by a baffle 4. The lower cylinder is the reaction chamber, and the upper cylinder carries and heats the gas source material 13, as shown in FIG. 6.

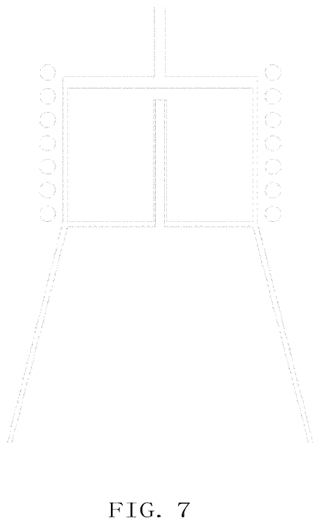

2. The upper part of the baffle plate 4 of the open air source device 3 is a cylindrical structure, and the lower part of the baffle plate 4 is a trumpet-shaped structure. The space formed by the trumpet-shaped structure is the reaction chamber, and the upper cylinder carries and heats the gas source material 13, as shown in FIG. 7.

Regardless of the structure, the vent holes and exhaust pipes described above can be arranged in the same manner.

Experiments have shown that the method of the present invention is 12 times more efficient than the traditional double-tube injection method. The reaction time is short, and the high-temperature phosphated steel melt is in contact with the steel for a short time, so the contamination is reduced accordingly, and the purity of the material is significantly improved.

1. A semiconductor compound injection synthesis method, completed by a synthesis system characterized in that:
the synthesis system adopts an open gas source device, the open gas source device is sealed at a top and open at a bottom, a diameter of the opening is smaller than an inner diameter of crucible, a baffle with air holes is set in a middle of the open gas source device, and a gas source heater is set on a periphery of the open gas source device;
the method comprising:
1-1, placing gas source material required for synthesis on the baffle of the open gas source device, and inserting the open gas source device into the crucible,
1-2, treating metal material required for synthesis, and placing the treated metal material into the crucible,
1-3, placing a covering agent on the metal material,
1-4, turning on a crucible heater,
1-5, after the metal material is melted, lowering the open gas source device that its lower edge is close to the bottom of the crucible,
1-6, raising a temperature of the crucible to the synthesis temperature,
1-7, turning on a gas source heater, and the gas source material is heated to a gasification temperature,
1-8, controlling a power of the gas source heater and adjusting a gasification rate of the gas source material,
1-9, finishing gasifying the gas source material, ending the reaction.

2. The semiconductor compound injection synthesis method according to claim 1 is characterized in that:
in step 1-8, a principle of controlling the power of the gas source heater is to keep a melt level in the open gas source device and a melt level in the crucible basically consistent.

3. The semiconductor compound injection synthesis method according to claim 1 is characterized in that:
in the open gas source device, a vent hole is provided at a lower part adjacent to the baffle, and the vent hole is opened and closed by a floating ball.

4. The semiconductor compound injection synthesis method according to claim 3, characterized in that:
two vents are provided, which are divided into an air inlet and an exhaust hole according to their functions.

5. The semiconductor compound injection synthesis method according to claim 4, characterized in that:
the exhaust hole is externally connected to an exhaust pipe, which extends to the lower edge of the open gas source device.

6. The semiconductor compound injection synthesis method according to claim 5, characterized in that:
one to six exhaust pipes are provided, which are evenly arranged along a periphery of the open gas source device.

7. The semiconductor compound injection synthesis method according to claim 4, characterized in that:
when the exhaust hole is blocked, a position of the float ball controlling the exhaust hole is lower than a position of the exhaust hole.

8. The semiconductor compound injection synthesis method according to claim 1, characterized in that: the open gas source device is a barrel structure.

9. The semiconductor compound injection synthesis method according to claim 1, characterized in that: the open gas source device comprises two barrel structures, and a diameter of the barrel below the baffle is larger than a diameter of the barrel above the baffle.

10. The semiconductor compound injection synthesis method according to claim 1, characterized in that: the open gas source device has a barrel structure above the baffle and a bell-mouth shape below the baffle.
